(19) United States
(12) Patent Application Publication
(10) Pub. No.: US 2005/0175861 A1
(43) Pub. Date: Aug. 11, 2005

(54) Polythiophene compositions for improving organic light-emitting diodes

(75) Inventors: Andreas Elschner, Mulheim (DE); Friedrich Jonas, Aachen (DE); Knud Reuter, Krefeld (DE); Peter Wilfried Lovenich, Koln (DE)

Correspondence Address: Norris, McLaughlin & Marcus P.A., 875 Third Avenue, 18th Floor, New York, NY, 10022, US

(73) Assignee: H.C. Starck GmbH, Goslar (DE)

(21) Appl. No.: 11/044,908

(22) Filed: Jan. 27, 2005

(30) Foreign Application Priority Data
Feb. 10, 2004 (DE) 10 2004 00 6583.7
Mar. 5, 2004 (DE) 10 2004 01 0811.0

(51) Int. Cl. H01B 1/12; H05B 33/12

(52) U.S. Cl. 428/690; 428/917; 313/504; 313/506; 257/40; 252/500

(57) ABSTRACT

Disclosed are compositions/formulations that include: polythiophenes (A) containing recurring units represented by the following general formula (I), 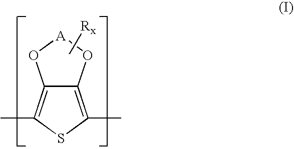
in which 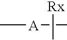
is, for example, —CH₂—CH₂—; and two additional polymers (B) and (C), each having SO₃⁻M⁺ or COO⁻M⁺ functional groups. Also disclosed are electroluminescent arrangements having hole-injecting layers containing the disclosed compositions.

### CROSS REFERENCE TO RELATED PATENT APPLICATION

The present patent application claims the right of priority under 35 U.S.C. §119 (a)-(d) of German Patent Application No. ______, filed Mar. 5, 2004.

### FIELD OF THE INVENTION

The invention relates to compositions/formulations comprising polythiophenes and further polymers, their use and electroluminescent arrangements comprising hole-injecting layers comprising these formulations.

### BACKGROUND OF THE INVENTION

An electroluminescent arrangement (EL arrangement) is characterized in that when an electrical voltage is applied, with flow of current, it emits light. Such arrangements have been known for a long time under the name “light-emitting diodes” (LEDs). The emission of light arises by positive charges (“holes”) and negative charges (“electrons”) recombining with emission of light.

The LEDs customary in the art are all predominantly made of inorganic semiconductor materials. However, EL arrangements in which the essential constituents are organic materials have been known for some years.

These organic EL arrangements as a rule comprise one or more layers of organic charge transportation compounds.

The main layer build-up of an EL arrangement is e.g. as follows:
1. Carrier, substrate
2. Base electrode
3. Hole-injecting layer
4. Hole-transporting layer
5. Emitter layer
6. Electron-transporting layer
7. Electron-injecting layer
8. Top electrode
9. Contacts
10. Casing, encapsulation

This build-up represents the most detailed case and can be simplified by omitting individual layers, so that one layer takes over several tasks. In the simplest case an EL arrangement comprises two electrodes, between which is an organic layer which fulfils all functions—including that of emission of light.

However, it has been found in practice that electron- and/or hole-injecting layers are particularly advantageous in electroluminescent constructions in order to increase the luminous density.

EP-A-686 662 discloses specific mixtures of conductive organic polymeric conductors, such as poly(3,4-ethylenedioxythiophene), and, for example, polyhydroxy compounds or lactams as electrodes in electroluminescence displays. However, it has been found in practice that these electrodes have an inadequate conductivity, especially for large-area displays. On the other hand, the conductivity is sufficient for small displays (luminous area<1 cm²).

DE-A-196 27 071 discloses the use of polymeric organic conductors, e.g. poly(3,4-ethylenedioxythiophene), as hole-injecting layers. By this means the luminous intensity of the electroluminescent displays can be increased significantly compared with constructions without the use of polymeric organic intermediate layers. By reducing the particle size of the poly(3,4-alkylenedioxythiophene) dispersions, the conductivity can be adjusted in a controlled manner. It is thus possible to prevent electrical crosstalk of adjacent address lines, especially in passive matrix displays (EP-A-1 227 529).

However, the life of these displays is still not sufficient for many practical uses.

There therefore continued to be a need for the production of EL arrangements which have, in addition to a high luminous intensity (luminous strength), a longer life than known EL arrangements.

### SUMMARY OF THE INVENTION

The object of the present invention was therefore to discover and to provide suitable formulations for the production of such EL arrangements. A further object was to produce improved EL arrangements from these materials.

It has been found, surprisingly, that hitherto unknown formulations comprising optionally substituted polythiophenes or optionally substituted polyanilines or polypyrroles and further polymers are outstandingly suitable for the production of hole-injecting layers for EL arrangements, and the EL arrangements obtained have significantly longer lives than known EL arrangements.

The present invention therefore provides compositions/formulations comprising
A) at least one polythiophene containing recurring units of the general formula (I) 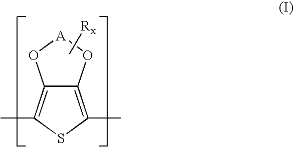
   wherein
   A represents an optionally substituted C₁-C₅-alkylene radical, preferably an optionally substituted ethylene or propylene radical, particularly preferably a 1,2-ethanediyl radical,
   R represents a linear or branched C₁-C₁₈-alkyl radical, preferably a linear or branched C₁-C₁₄-alkyl radical, particularly preferably a methyl or ethyl radical, a C₅-C₁₂-cycloalkyl radical, a C₆-C₁₄-aryl radical, a C₇-C₁₈-aralkyl radical, a C₁-C₄-hydroxyalkyl radical or a hydroxyl radical,
   x represents an integer from 0 to 8, preferably 0, 1 or 2, particularly preferably 0 or 1 and
      in the case where several radicals R are bonded to A, these can be identical or different,
B) at least one polymer containing SO₃⁻M⁺ or COO⁻M⁺ groups, wherein M⁺ represents H⁺, Li⁺, Na⁺ K⁺, Rb⁺, Cs⁺ or NH₄⁺, preferably H⁺, Na⁺ or K⁺, and
C) at least one partly fluorinated or perfluorinated polymer containing SO₃⁻M⁺ or COO⁻M⁺ groups, wherein M⁺ represents H⁺, Li⁺, Na⁺ K⁺, Rb⁺, Cs⁺ or NH₄⁺, preferably H⁺, Na⁺ or K⁺.

The general formula (I) is to be understood as meaning that the substituent R can be bonded to the alkylene radical A x times.

Polymers (B) and (C) are different from each other and are each different than polythiophene (A).

Unless otherwise indicated, all numbers or expressions, such as those expressing quantities of ingredients, process conditions, etc., used in the specification and claims are understood as modified in all instances by the term “about.”

### DETAILED DESCRIPTION OF THE INVENTION

Formulation within the meaning of the invention may be any mixture of components A), B) and C) as solids, in solution or in dispersion.

Instead of Polythiophene A) any other known conducting polymer A) can be used in the mixture, in particular, optionally substituted polyaniline or polypyrrole.

These different conducting polymers A) can be used alone or in any mixture.

Here and below the term substituted means if not otherwise indicated a substitution with chemical group selected from the group consisting of:
alkyl, in particular C₁-C₂₀-alkyl, cycloalkyl, in particular C₃-C₂₀-cycloalkyl, aryl, in particular C₆-C₁₄-aryl, halogen, in particular Cl, Br, J, ether, thioether, disulfide, sulfoxide, sulfone, amino, aldehyde, keto, carboxylic acid ester, cyano, alkylsilane and alkoxysilane groups as well as carboxylamide groups.

In preferred embodiments of the formulation according to the invention, at least one polythiophene
A) containing recurring units of the general formula (I) is one containing recurring units of the general formula (Ia) 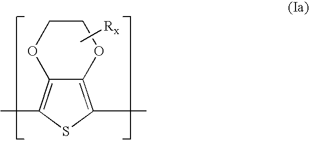
   wherein
R and x have the abovementioned meaning.

In very particularly preferred formulations according to the above description, x represents 0 or 1. In the case where x is 1, R particularly preferably represents methyl or hydroxymethyl.

In further preferred embodiments of the formulation according to the invention, at least one polythiophene containing recurring units of the general formula (I) is one containing recurring units of the general formula (Iaa)

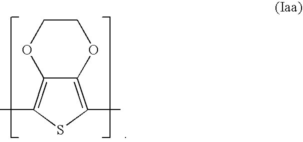

In the context of the invention, the prefix poly- is to be understood as meaning that more than one identical or different recurring unit is contained in the polymer or polythiophene. The polythiophenes contain a total of n recurring units of the general formula (I), wherein n can be an integer from 2 to 2,000, preferably 2 to *100. The recurring units of the general formula (I) can in each case be identical or different within a polythiophene. Polythiophenes containing in each case identical recurring units of the general formula (I) are preferred.

In the context of the invention, recurring units are units of the general formulae (I), (Ia) or (Iaa), summarized as recurring units of the general formula (I) in the following, regardless of whether they are contained once or several times in the polythiophene. That is to say, units of the general formula (I) are also to be understood as recurring units if they are contained in the polythiophene only once.

Formulations according to the invention can also be those which comprise in the mixture, in addition to at least one of the polythiophenes A) described above containing recurring units of the general formula (I), further conductive polymers A), such as, for example, polyanilines or polypyrroles.

The polythiophenes A) preferably in each case carry H on the end groups.

The polythiophenes A) contain a total of n recurring units of the general formula (I), wherein n preferably is an integer from 2 to 1,000, preferably 3 to 100, particularly preferably 4 to 15.

In the context of the invention, C₁-C₅-alkylene radicals A are particularly methylene, ethylene, n-propylene, n-butylene or n-pentylene. In particular, C₁-C₁₈-alkyl represents linear or branched C₁-C₁₈-alkyl radicals, such as, for example, methyl, ethyl, n- or iso-propyl, n-, iso-, sec- or tert-butyl, n-pentyl, 1-methylbutyl, 2-methylbutyl, 3-methylbutyl, 1-ethylpropyl, 1,1-dimethylpropyl, 1,2-dimethylpropyl, 2,2-dimethylpropyl, n-hexyl, n-heptyl, n-octyl, 2-ethylhexyl, n-nonyl, n-decyl, n-undecyl, n-dodecyl, n-tridecyl, n-tetradecyl, n-hexadecyl or n-octadecyl, C₅-C₁₂-cycloalkyl represents C₅-C₁₂-cycloalkyl radicals, such as, for example, cyclopentyl, cyclohexyl, cycloheptyl, cyclooctyl, cyclononyl or cyclodecyl, C₇-C₁₄-aryl represents C₅-C₁₄-aryl radicals, such as, for example, phenyl or naphthyl, and C₇-C₁₈-aralkyl represents C₇-C₁₈-aralkyl radicals, such as, for example, benzyl, o-, m- or p-tolyl, 2,3-, 2,4-, 2,5-, 2,6-, 3,4- or 3,5-xylyl or mesityl. The above list serves to explain the invention by way of example and is not to be regarded as conclusive.

The preparation of the polythiophenes A) described above containing recurring units of the general formula (I) is described in principle in EP-A 440 957.

The polymerization of the corresponding monomeric starting compounds is carried out with suitable oxidizing agents in suitable solvents. Examples of suitable oxidizing agents are iron(III) salts, in particular FeCl₃ and iron(III) salts of aromatic and aliphatic sulfonic acids, H₂O₂, K₂Cr₂O₇, K₂S₂O₈, Na₂S₂O₈, KMnO₄, alkali metal perborates and alkali metal or ammonium persulfates or mixtures of these oxidizing agents. Further suitable oxidizing agents are described, for example, in Handbook of Conducting Polymers (ed. Skotheim, T. A.), Marcel Dekker: New York, 1986, vol. 1, 46-57. Particularly preferred oxidizing agents are FeCl₃, Na₂S₂O₈ and K₂S₂O₈ or mixtures thereof. The polymerization is preferably carried out at a reaction temperature of −20 to 100° C. Reaction temperatures of 20 to 100° C. are particularly preferred. If appropriate, the reaction solution is then treated with at least one ion exchanger.

Suitable solvents for the above mentioned reaction are e.g. polar solvents, such as, for example, water, alcohols, such as methanol, ethanol, 2-propanol, n-propanol, n-butanol, diacetone alcohol, ethylene glycol, glycerol or mixtures of these. Aliphatic ketones, such as acetone and methyl ethyl ketone, aliphatic nitriles, such as acetonitrile, aliphatic and cyclic amides, such as N,N-dimethylacetamide, N,N-dimethylformamide (DMF) and 1-methyl-2-pyrrolidone (NMP), ethers, such as tetrahydrofuran (THF), and sulfoxides, such as dimethylsulfoxide (DMSO), or mixtures of these with one another or with the abovementioned solvents are also suitable.

The corresponding monomeric compounds for the preparation of polythiophenes A) containing recurring units of the general formula (I) are known. Their preparation is possible, for example, by reaction of the alkali metal salts of 3,4-dihydroxythiophene-2,5-dicarboxylic acid esters with the corresponding alkylene dihalides and subsequent decarboxylation of the free 3,4-(alkylenedioxy)thiophene-2,5-dicarboxylic acids (see e.g. Tetrahedron 1967, 23, 2437-2441 and J. Am. Chem. Soc. 1945, 67, 2217-2218).

The resulting polythiophenes are very readily soluble or dispersible in the polar solvents or solvent mixtures.

The formulations according to the invention comprise, in addition to at least one partly fluorinated or perfluorinated polymer C), at least one further polymer C) containing SO₃⁻M⁺ or COO⁻M⁺ groups. Polymers B) containing SO₃⁻M⁺ or COO⁻M⁺ groups which are suitable are preferably those which contain no completely conjugated main chain, also abbreviated to non-conjugated in the following. Examples which may be mentioned of suitable polymers B) containing SO₃⁻M⁺ or COO⁻M⁺ groups are polymeric carboxylic acids, such as polyacrylic acids, polymethacrylic acid or polymaleic acids, or polymeric sulfonic acids, such as polystyrenesulfonic acids and polyvinylsulfonic acids. Copolymers of vinylcarboxylic and vinylsulfonic acids with other polymerizable monomers, such as acrylic acid esters and styrene, are furthermore also possible. Polystyrenesulfonic acid, poly-(styrenesulfonic acid-co-maleic acid) or poly-(vinylsulfonic acid) are particularly suitable. Very particularly suitable formulations are characterized in that they comprise polystyrenesulfonic acid (PSS) as at least one polymer B) containing SO₃⁻M⁺ or COO⁻M⁺ groups.

These polymers B) are preferably soluble or dispersible in polar solvents, such as water, alcohols, such as methanol, ethanol, 2-propanol, n-propanol, n-butanol, diacetone alcohol, ethylene glycol and glycerol, aliphatic ketones, such as acetone and methyl ethyl ketone, aliphatic nitriles, such as acetonitrile, aliphatic and cyclic amides, such as N,N-dimethylacetamide, N,N-dimethylformamide (DMF) and 1-methyl-2-pyrrolidone (NMP), ethers, such as tetrahydrofuran (THF), and sulfoxides, such as dimethylsulfoxide (DMSO), or mixtures containing these, preferably in water, alcohols, such as methanol, ethanol, 2-propanol and n-butanol, or mixtures of these.

Particularly suitable formulations according to the above description are characterized in that they comprise as at least one partly fluorinated or perfluorinated polymer C) containing SO₃⁻M⁺ or COO⁻M⁺ groups, for example, those containing recurring units of the formulae (II-a) and (II-b) 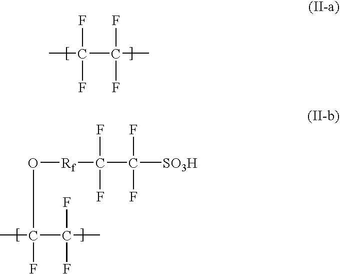
wherein R_{f} represents a radical having at least one, preferably 1 to 30 recurring unit(s) of the formula (II-c)

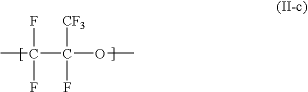

Such perfluorinated polymers C) are, for example, the polymers which are commercially obtainable under the trade name Nafion® (copolymer of tetrafluoroethylene and of the trifluorovinylether of poly(hexafluoro propylene oxide)mono(tetrafluoro vinyl sulfonic acid)ethers) or in dissolved form under the trade name Liquion®.

In particularly preferred embodiments, the new formulation according to the invention comprises Nafion® as at least one polymer C) containing SO₃⁻M⁺ or COO⁻M⁺ groups.

Formulations which comprise polystyrenesulfonic acid (PSS) as the polymer B) containing SO₃⁻M⁺ or COO⁻M⁺ groups and Nafion® as the partly fluorinated or perfluorinated polymer C) containing SO₃⁻M⁺ or COO⁻M⁺ groups are particularly preferred.

The molecular weight of the poly-acids is preferably 1,000 to 2,000,000, particularly preferably 2,000 to 500,000. The poly-acids or their alkali metal salts are commercially obtainable, e.g. polystyrenesulfonic acids and polyacrylic acids, or can be prepared by known processes (see e.g. Houben Weyl, Methoden der organischen Chemie, vol. E 20 Makromolekulare Stoffe, part 2, (1987), p. 1141 et seq.).

Very particularly preferred are formulations, in which the weight ratio of polythiophene(s) A) to polymer(s) C) containing SO₃⁻M⁺ or COO⁻M⁺ groups is from 1 to 2 (1:2) to 1 to 25 (1:25), preferably 1 to 2 (1:2) to 1 to 10 (1:10).

Furthermore very particularly preferred are formulations, in which the weight ratio of polythiophene(s) A) to partly fluorinated or perfluorinated polymer(s) C) containing SO₃⁻M⁺ or COO⁻M⁺ groups is from 1 to 1 (1:1) to 1 to 15 (1:15), preferably 1 to 2 (1:2) to 1 to 10 (1:10).

All desired combinations of the two weight ratios described above for polythiophene(s) A) to polymer(s) B) containing SO₃⁻M⁺ or COO⁻M⁺ groups and polythiophene(s) A) to partly fluorinated or perfluorinated polymer(s) C) containing SO₃⁻M⁺ or COO⁻M⁺ groups can be realized in the preferred formulations and are regarded as disclosed herewith.

The new formulations can furthermore additionally comprise at least one polar diluent D) (polar solvent). In the context of the invention, polar diluents D) (polar solvents) are to be understood as meaning diluents having a solubility parameter δ of 16 MPa^{1/2} and above, preferably 19 MPa^{1/2} and above. Solubility parameters are as a rule measured at the standard temperature (20° C.). For measurement and calculation of solubility parameters, see J. Brandrup et al., Polymer Handbook, 4th ed., 1999, VII/675-VII/688. Solubility parameters are given in tabular form e.g. in J. Brandrup et al., Polymer Handbook, 4th ed., 1999, VII/688-VII/697. Preferred polar diluents are water, alcohols, such as methanol, ethanol, 2-propanol, n-propanol, n-butanol, diacetone alcohol, ethylene glycol and glycerol, aliphatic ketones, such as acetone and methyl ethyl ketone, aliphatic nitriles, such as acetonitrile, aliphatic and cyclic amides, such as N,N-dimethylacetamide, N,N-dimethylformamide (DMF) and 1-methyl-2-pyrrolidone (NMP), ethers, such as tetrahydrofuran (THF), and sulfoxides, such as dimethylsulfoxide (DMSO), or mixtures containing these. Particularly preferred polar diluents D) are water, alcohols or mixtures containing these, and water, methanol, ethanol, n-propanol, 2-propanol or n-butanol or mixtures containing these are very particularly preferred. In preferred embodiments, the new formulations comprise mixtures of water and at least one alcohol as the polar diluent D).

Such new preferred formulations comprising at least one polar diluent D) preferably comprise 99.99 to 80 wt. %, particularly preferably 99.8 to 95 wt. % of polar diluent(s) D) and have a solids content of 0.01 to 20 wt. %, particularly preferably 0.2 to 5 wt. %, i.e. comprise in total 0.01 to 20 wt. %, particularly preferably 0.2 to 5 wt. % of polythiophene(s) A), polymers B) and C) containing SO₃⁻M⁺ or COO⁻M⁺ groups and optionally further components, such as e.g. binders, crosslinking agents and/or surfactants, in dissolved and/or dispersed form.

The viscosity at 20° C. of the new preferred formulations comprising at least one polar diluent D) is between the viscosity of the diluent and 200 mPas, preferably <100 mPas.

To establish the desired solids content and the required viscosity, the desired amount of diluent can be removed from the formulations by distillation, preferably in vacuo, or by other processes, e.g. ultrafiltration.

Organic, polymeric binders and/or organic, low molecular weight crosslinking agents or surfactants can moreover be added to the formulations according to the invention. Corresponding binders are described e.g. in EP-A-564 911. Examples which may be mentioned here are polyvinylcarbazole as binder, silanes, such as Silquest® A187 (OSi specialities) as crosslinking agent, or surfactants, such as the fluorosurfactant FT 248 (Bayer AG).

The formulations can preferably comprise only small amounts of ionic impurities in the limits such as are described in EP-A-991 303. The formulations preferably comprise less than 1,000 ppm of ionic impurities.

The formulations according to the invention can be prepared in a simple manner. For example, it is possible to mix an already finished mixture comprising at least one polymer B) containing SO₃⁻M⁺ or COO⁻M⁺ groups and at least one polythiophene A) with at least one partly fluorinated or perfluorinated polymer C) containing SO₃⁻M⁺ or COO⁻M⁺ groups and optionally to add at least one diluent to this mixture, preferably to completely or partly dissolve or disperse this mixture in at least one diluent. It is also possible to add to an already finished mixture comprising a polymer B) containing SO₃⁻M⁺ or COO⁻M⁺ groups and at least one polythiophene A) at least one diluent D) beforehand, preferably to completely or partly dissolve or disperse this finished mixture in at least one diluent D), to dissolve or disperse at least one partly fluorinated or perfluorinated polymer C) containing SO₃⁻M⁺ or COO⁻M⁺ groups in a diluent D) and then to mix the solution(s) and/or dispersion(s). If appropriate, all or some of the diluent or diluent mixture D) can be removed again from this mixture, e.g. by distillation or other processes.

Surprisingly, the formulations according to the invention are outstandingly suitable for the production of hole-injecting or hole-transporting layers in EL arrangements, organic solar cells, organic laser diodes, organic thin film transistors or organic field effect transistors, for the production of electrodes or electrically conductive coatings.

The present invention therefore also provides the use of the formulations according to the invention for the production of hole-injecting layers in EL arrangements, for the production of electrodes or electrically conductive coatings.

These EL-Arrangements can be used as displays, e.g. in flat screens in lap-tops, pagers, mobile phones, navigation systems, (car-)radios, (car)-control panels, or as planar beamer, e.g. in lamps, background lightings of LCD-displays or signboards.

EL arrangements having a hole-injecting layer comprising a formulation according to the invention are distinguished in particular by a high luminous intensity (luminous strength) and a significantly longer life than known EL arrangements.

The present invention therefore also provides EL arrangements, in particular light emitting diodes comprising a hole-injecting layer comprising a formulation according to the invention. These are preferably those EL arrangements comprising at least two electrodes, of which optionally at least one is applied to an optionally transparent substrate, at least one emitter layer between the two electrodes and at least one hole-injecting layer between one of the two electrodes and the emitter layer, characterized in that the hole-injecting layer comprises a formulation according to the invention.

In the production of many EL arrangements of large area, e.g. electroluminescent display elements of large area, it is advantageous if at least one of the current-carrying electrodes is made of a transparent and conductive material. Examples of suitable such transparent and conductive electrode materials are
a) metal oxides, e.g. indium tin oxide (ITO), tin oxide (NESA), doped tin oxide, doped zinc oxide etc.,
b) semi-transparent metal films, e.g. Au, Pt, Ag, Cu etc.,
c) semi-transparent conductive polymers, e.g. polythiophenes, polyanilines, polypyrroles etc.

An electrode which is not made of one of the abovementioned transparent and conductive materials is preferably a metal electrode, in particular a metal cathode.

Suitable materials for metal cathodes are customary for electrooptical constructions and are known to the expert. Possible metal cathodes are, preferably, those of metals of low work of emission, such as Mg, Ca or Ba, or metal salts, such as LiF.

Suitable optionally transparent substrates are, for example, glass, extra-thin glass (flexible glass) or plastics, preferably films of plastic.

Particularly suitable plastics for the substrate are: polycarbonates, polyesters, such as e.g. PET and PEN (polyethylene terephthalate or polyethylene-naphthalene dicarboxylate), copolycarbonates, polyacrylate, polysulfone, polyether sulfone (PES), polyimide, polyethylene, polypropylene or cyclic polyolefins or cyclic olefin copolymers (COC), hydrogenated styrene polymers or hydrogenated styrene copolymers.

Suitable polymer substrates can be, for example, films, such as polyester films, PES films from Sumitomo or polycarbonate films from Bayer AG (Makrofol®).

An adhesion promoter layer can be located between the substrate and the electrode. Suitable adhesion promoters are, for example, silanes. Epoxysilanes, such as, for example, 3-glycidoxypropyltrimethoxysilane (Silquest® A187, OSi specialities) are preferred. Other adhesion promoters with hydrophilic surface properties can also be used. Thus e.g. a thin layer of PEDT:PSS is described as a suitable adhesion promoter for PEDT (Hohnholz et al., Chem. Commun. 2001, 2444-2445).

The emitter layer of the EL arrangement according to the invention comprises at least one emitter material. Suitable emitter materials are those which are customary for electrooptical constructions and known to the expert. Preferred possible emitter materials are conjugated polymers, such as polyphenylene-vinylene and/or polyfluorenes, such as the polyparaphenylene-vinylene derivatives and polyfluorene derivatives described, for example, in WO-A 90/13148, or emitters from the class of low molecular weight emitters, also called “small molecules” in technical circles, such as aluminium complexes, e.g. tris(8-hydroxyquinolinato)aluminium (Alq₃), fluorescent dyestuffs, e.g. quinacridones, or phosphorescent emitters, e.g. Ir(ppy)₃. Emitter materials are described e.g. in DE-A 196 27 071.

In addition to the abovementioned layers, further functional layers can be contained in such an electroluminescent layer build-up (EL arrangement), such as e.g. further charge-injecting, e.g. electron-injecting, charge-transporting or charge-blocking intermediate layers. Such layer constructions are known to the expert and are described, for example, in J. R. Sheats et al., Science 273, (1996), 884. One layer can also take over several tasks. For example, the abovementioned emitter materials can be employed in combination with a hole-transporting intermediate layer between the hole-injecting and emitter layer (cf. e.g. U.S. Pat. No. 4,539,507 and U.S. Pat. No. 5,150,006).

The production in principle of such EL arrangements is known to the expert. For example, they can be produced by applying an electrode to a substrate from solution or dispersion or by vapour deposition. For example, metal oxide or semi-transparent metal film electrodes are preferably applied to the substrate by vapour deposition, while semi-transparent, conductive polymer electrodes are preferably applied from solution or dispersion. If appropriate, an adhesion promoter can be applied—by vapour deposition or from solution or dispersion—before application of the electrode material to the substrate. Some such substrates coated with electrode material are also already commercially obtainable (e.g. K glass, ITO-coated glass substrates). The hole-injecting layer can then be applied to the electrode, which in the case of the EL arrangements according to the invention with a hole-injecting layer comprising a formulation according to the invention advantageously takes place from solution or dispersion. The further layers are then applied to the hole-injecting layer in the sequence given in the introduction—taking into account that individual layers can be omitted—from solution or dispersion or by vapour deposition, depending on the material employed. The layer arrangement is contacted and encapsulated.

The production of the hole-injecting layer comprising a formulation according to the invention is carried out by known technologies. For this, a formulation according to the invention—optionally in a solvent—is applied as a film to an electrode, preferably the base electrode. Suitable solvents are the abovementioned polar diluents D), preferably water, alcohols or mixtures of these. Suitable alcohols are e.g. methanol, ethanol, n-propanol, 2-propanol and n-butanol.

The use of these solvents has the advantage that further layers can be applied from organic solvents, such as aromatic or aliphatic hydrocarbon mixtures, without the hole-injecting layer being attacked.

The formulation according to the invention—optionally in a solvent—can be distributed uniformly on the electrode, for example, by techniques such as spin-coating, casting, knife-coating, printing, curtain casting etc. The layers can then be dried at room temperature or temperatures up to 300° C., preferably 100 to 200° C.

The formulation according to the invention—optionally in a solvent—can moreover preferably be applied in structured form by printing techniques such as ink-jet. This technique is known to the expert and, with the use of water-soluble and dispersed polythiophenes, such as 3,4-polyethylenedioxythiophene:polystyrenesulfonic acid (PEDT:PSS), is described e.g. in Science, vol. 279, 1135, 1998 and DE-A 198 41 804.

The formulations according to the invention—if appropriate in a solvent—are preferably filtered through a filter before the application.

Formulations which can be filtered for cleaning purposes particularly easily are obtained for example if, in a solvent D) based on one part by weight of polythiophene(s) A) containing recurring units of the general formula (I), preferably 1 to 30 parts-by weight, particularly preferably 2 to 25 parts by weight of the polymer(s) B) containing SO₃⁻M⁺ or COO⁻M⁺ groups are used.

The thickness of the hole-injecting layer is, for example, 3 to 500 nm, preferably 10 to 200 nm.

The influence of a hole-injecting layer comprising a formulation according to the invention on the properties of the EL arrangement can be tested in a specific build-up of such an EL arrangement according to the invention. For this, the hole-injecting layer is applied by means of a spin coater to an ITO substrate which has been cleaned by wet chemistry. The layer is then dried at 100-200° C. for 5 min. The layer thickness is 20-300 nm, depending on the spinning speed. A 1 wt. % strength solution of a polyfluorene-based emitter material (Green 1300 LUMATION™ from Dow Chemical Company) in xylene is spun on as the emitter layer. The thickness of the emitter layer is typically 60-120 nm. Finally, a Ba layer 5 nm thick and on this an Ag layer 200 nm thick are vapour-deposited as the cathode. By contacting of the indium tin oxide (ITO) anode and the metal cathode, current/voltage/luminous density characteristic lines are plotted by means of a characteristic line recorder and a calibrated photodiode and the lives are recorded. For this, the arrangement is charged with a constant electric current or an alternating current and the voltage and the luminous density are monitored as a function of time.

The organic light-emitting diodes according to the invention are distinguished by a long life, high luminous intensity, low use voltages and a high rectification ratio. In contrast to known light-emitting diodes with hole-injecting layers produced from a poly(3,4-ethylenedioxythiophene):polystyrenesulfonic acid (PEDT:PSS) dispersion (Baytron® P, H.C. Starck GmbH), it has been found, surprisingly, that the lives of organic light-emitting diodes according to the invention with a hole-injecting layer comprising a formulation according to the invention are significantly longer.

### EXAMPLES

### Example 1

### Preparation of a Formulation from poly(3,4-ethylenedioxythiophene)/polystyrenesulfonic Acid and a Perfluorinated Polymer

40 g of a 1.32% strength poly(3,4-ethylenedioxythiophene)/polystyrenesulfonic acid solution (H.C. Starck GmbH, Baytron® P, trial product TP AI 4083, weight ratio of PEDT/PSS is 1:6) are mixed with 9.96 g of a 5.30 wt. % strength solution of Nafion® in a mixture of lower aliphatic alcohols and water (Nafion® perfluorinated ion-exchange resin, 5 wt. % solution in lower aliphatic alcohols/H₂O, CAS no. 66796-30-3, Aldrich order no. 27,470-4, verified solids content 5.30 wt. %). The weight ratio of PEDT/PSS/Nafion® is 1:6:7.

### Example 2

The formulation according to the invention from example 1 is used to build up an organic light-emitting diode (OLED). The procedure for production of the OLED is as follows:

1. Preparation of the ITO-Coated Substrate

ITO-coated glass (Merck Balzers AG, FL, part no. 253 674 XO) is cut into pieces 50 mm×50 mm in size (substrates). The ITO layer is structured with the conventional photoresist technique and subsequent etching away in FeCl₃ solution. The ITO strips isolated have a width of 2.0 mm. The substrates are then cleaned in 3% strength aqueous Mucasol solution in an ultrasonic bath for 15 min. Thereafter, the substrates are rinsed with distilled water and spun dry in a centrifuge. This rinsing and drying operation is repeated 10 times. Directly before the coating, the ITO-coated sides are cleaned for 10 min in a UV/ozone reactor (PR-100, UVP Inc., Cambridge, GB).

2. Application of the Hole-Injecting Layer

About 10 ml of the formulation according to the invention from example 1 are filtered (Millipore HV, 0.45 μm). The cleaned ITO-coated substrate is placed on a lacquer spin-coater and the filtered solution is distributed over the ITO-coated side of the substrate. The supernatant solution is then spun off by rotating the plate at 800 rpm over a period of 30 s with the lid closed. Thereafter, the substrate coated in this way is dried for 5 min at 200° C. on a hot-plate. The layer thickness is 85 nm (Tencor, Alphastep 500).

3. Application of the Emitter Layer

5 ml of a 1 wt. % strength xylene solution of the emitter Green 1300 LUMATION™ (Dow Chemical Company) are filtered (Millipore HV, 0.45 μm) and distributed over the dried hole-injecting layer. This and all the further process steps are carried out in pure N₂ atmosphere (Inert Gas Glovebox System, M. Braun, Garching). The hole injection layer is after-dried beforehand in the glove box for a further 5 min at 200° C. The supernatant solution of the emitter is then spun off by rotating the plate at 400 rpm for 30 s with the lid closed. Thereafter, the substrate coated in this way is dried for 15 min at 130° C. on a hot-plate. The total layer thickness is 185 nm.

4. Application of the Metal Cathode

A metal electrode is vapour-deposited on to the emitter layer. The substrate is placed with the emitter layer downwards on a strip mask with strips 2.0 mm wide, which is orientated perpendicular to the ITO strips. A Ba layer 5 nm thick and then an Ag layer 200 nm thick are vapour-deposited in succession from two vapour deposition boats under a pressure of p=10⁻³ Pa. The vapour deposition rates are 10 Å/s for Ba and 20 Å/s for Ag. The active luminous area at the crossing point of the two electrodes is 4 mm².

5. Encapsulation of the OLEDs

The readily oxidizable cathodes are protected from corrosion by encapsulation. For this, the polymeric layers are removed manually at the edge of the substrate using a scalpel and a metal cap (35 mm×35 mm×2 mm) is glued on with an epoxy adhesive (UHU Plus, UHU, D) as protection. A moisture absorber (GDO/CA/18×10×0.4, SAES Getters S.p.A., Italy) is additionally placed in the metal cap.

6. Characterization of the OLED

The two electrodes of the organic LED are connected (contacted) to a voltage source via electrical leads. The positive pole is connected to the ITO electrode and the negative pole is connected to the metal electrode. The dependence of the OLED current and the electroluminescence intensity (detection is with a photodiode (EG&G C30809E)) on the voltage is recorded. The lives are then determined by allowing a constant current of I=0.32 mA (8 nA/cm²) to flow through the arrangement and monitoring the voltage and light intensity as a function of time.

### Comparison Example 2.1

Production of an OLED with poly(3,4-ethylenedioxythiophene)/polystyrenesulfonic acid as the hole-injecting layer:

The procedure is as in example 2, with the following deviation in process step 2.

2. Application of the Hole Injection Layer

About 10 ml of a 1.3% strength poly(3,4-ethylenedioxythiophene)/polystyrenesulfonic acid solution (H.C. Starck GmbH, Baytron® P, TP AI 4083) are filtered (Millipore HV, 0.45 μm). The ITO-coated substrate is then placed on a lacquer spin-coater and the filtered solution is distributed over the ITO-coated side of the substrate. The supernatant solution is then spun off by rotating the plate at 600 rpm over a period of 30 s with the lid closed. Thereafter, the substrate coated in this way is dried for 5 min at 200° C. on a hot-plate. The layer thickness is 85 mm.

The metal cathodes were applied in accordance with process step 4 together with the layer construction from example 2 in order to ensure comparability.

Results of the measurements of the lives of the arrangements from example 2 and comparison examples 2.1 at a constant current (I=8 mA/cm²).

| | t = 0 | | t = 260 h | |
|---|---|---|---|---|
| | U/[V] | L/[rel. unit] | U/[V] | L/[rel. unit] |
| OLED from example 2 | 3.66 | 6.81 | 3.88 | 6.61 |
| OLED from comparison | 3.71 | 4.66 | 4.13 | 2.59 |
| example 2.1 | | | | |

The EL arrangement according to the invention with the hole-injecting layer comprising the formulation according to the invention (example 1) is more efficient and has a significantly longer life compared with the EL arrangement which is built up with a hole-injecting layer of a known material (PEDT:PSS from comparison example 2.1). After a long-term test of 260 h, not only the decrease in the electroluminescence intensity but also the increase in voltage is lower.

### Example 3.1

### Preparation of a Formulation from poly(3,4-ethylenedioxythiophene)/polystyrenesulfonic Acid and a Perfluorinated Polymer

15 g of a desalinated 1.36% strength polyethylenedioxythiophene/polystyrenesulfonic acid solution (H.C. Starck GmbH, Baytron® P, TP AI 4083 desalinated) are mixed with 4.09 g Nafion® solution (Liquion® 1000, 5 wt. % strength solution in 2-propanol/H₂O, 1000 eq., Ion Power Inc., US). The weight ratio of PEDT/PSS to Nafion® corresponds to 1:1.

### Example 3.2

### Preparation of a Formulation from poly(3,4-ethylenedioxythiophene)/polystyrenesulfonic Acid and a Perfluorinated Polymer

12 g of a desalinated 1.36% strength polyethylenedioxythiophene/polystyrenesulfonic acid solution (H.C. Starck GmbH, Baytron® P, TP AI 4083 desalinated) are mixed with 3.42 g Nafion® solution (Liquion® 1100, 5 wt. % strength solution in 2-propanol/H₂O, 1100 eq., Ion Power Inc., US). The weight ratio of PEDT/PSS to Nafion® corresponds to 1:1.

### Example 4.1

The formulation according to the invention from example 3.1 is used to build up an organic light-emitting diode (OLED). The procedure for the production of the OLED is as in example 2, with the following deviation in process step 2.

2. Application of the Hole Injection Layer

About 10 ml of the formulation according to the invention from example 3.1 are filtered (Millipore HV, 0.45 μm). The cleaned ITO-coated substrate is placed on a lacquer spin-coater and the filtered solution is distributed over the ITO-coated side of the substrate. The supernatant solution is then spun off by rotating the plate at 800 rpm over a period of 30 s with the lid closed. Thereafter, the substrate coated in this way is dried for 5 min at 200° C. on a hot-plate. The layer thickness is 85 nm (Tencor, Alphastep 500).

### Example 4.2

The formulation according to the invention from example 3.2 is used to build up an organic light-emitting diode (OLED). The procedure for the production of the OLED is as in example 2, with the following deviation in process step 2.

2. Application of the Hole Injection Layer

About 10 ml of the formulation according to the invention from example 3.2 are filtered (Millipore HV, 0.45 μm). The cleaned ITO-coated substrate is placed on a lacquer spin-coater and the filtered solution is distributed over the ITO-coated side of the substrate. The supernatant solution is then spun off by rotating the plate at 800 rpm over a period of 30 s with the lid closed. Thereafter, the substrate coated in this way is dried for 5 min at 200° C. on a hot-plate. The layer thickness is 85 nm (Tencor, Alphastep 500).

### Comparison Example 4.3

Production of an OLED with poly(3,4-ethylenedioxythiophene)/polystyrenesulfonic Acid as the Hole-Injecting Layer:

The procedure is as in example 2, with the following deviation in process step 2.

2. Application of the Hole Injection Layer

About 10 ml of a desalinated 1.36% strength poly(3,4-ethylenedioxythiophene)/polystyrenesulfonic acid solution (H.C. Starck GmbH, Baytron® P TP AI 4083) are filtered (Millipore HV, 0.45 μm). The ITO-coated substrate is then placed on a lacquer spin-coater and the filtered solution is distributed over the ITO-coated side of the substrate. The supernatant solution is then spun off by rotating the plate at 600 rpm over a period of 30 s with the lid closed. Thereafter, the substrate coated in this way is dried for 5 min at 200° C. on a hot-plate. The layer thickness is 85 nm.

The metal cathodes were applied in accordance with process step 4 together with the layer constructions from examples 4.1 and 4.2 in order to ensure comparability.

Results of the measurements of the lives of the arrangements from examples 4.1, 4.2 and comparison example 4.3 at a constant current (I=24 mA/cm²).

| | t = 0 | | t = 100 h | |
|---|---|---|---|---|
| | U/[V] | L/[rel. unit] | U/[V] | L/[rel. unit] |
| OLED from example 4.1 | 4.19 | 7.58 | 4.40 | 6.95 |
| OLED from example 4.2 | 4.30 | 7.67 | 4.51 | 7.02 |
| OLED from comparison | 4.02 | 6.29 | 4.43 | 4.75 |
| example 4.3 | | | | |

The EL arrangements according to the invention with the hole-injecting layer comprising the formulations according to the invention (examples 4.1 and 4.2) are more efficient and have significantly longer lives compared with the EL arrangement which is built up with a hole-injecting layer of a known material (PEDT:PSS from comparison example 4.3). After a long-term test of 100 h at a high device current, not only the decrease in the electroluminescence intensity but also the increase in voltage is lower in the EL arrangements according to the invention.

Although the invention has been described in detail in the foregoing for the purpose of illustration, it is to be understood that such detail is solely for that purpose and that variations can be made therein by those skilled in the art without departing from the spirit and scope of the invention except as it may be limited by the claims.

1. A composition comprising:
A) at least one polythiophene containing recurring units represented by the following general formula (I), 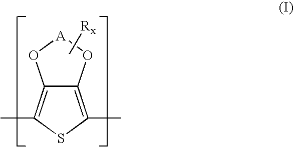
wherein
A represents a substituted or unsubstituted C₁-C₅-alkylene radical, R represents, independently for each x, a member selected from the group consisting of a linear or branched C₁-C₁₈-alkyl radical, a C₅-C₁₂-cycloalkyl radical, a C₆-C₁₄-aryl radical, a C₇-C₁₈-aralkyl radical, a C₁-C₄-hydroxyalkyl radical and a hydroxyl radical, and
x represents an integer from 0 to 8; and
B) at least one polymer, that is different than polythiophene (A), and which contains SO₃⁻M⁺ groups or COO⁻M⁺ groups, wherein M⁺ is a member selected from the group consisting of H⁺, Li⁺, Na⁺ K⁺, Rb⁺, Cs⁺ and NH₄⁺; and
C) at least one polymer, that is different than polythiophene (A) and polymer (B), and which is selected from the group consisting of partially fluorinated polymers, perfluorinated polymers and combinations thereof, wherein polymer (C) contains SO₃⁻M⁺ groups or COO⁻M⁺ groups, wherein M⁺ is a member selected from the group consisting of H⁺, Li⁺, Na⁺ K⁺, Rb⁺, Cs⁺ and NH₄⁺.

2. The composition of claim 1 wherein said polythiophene (A) contains recurring units represented by the following general formula (Ia), 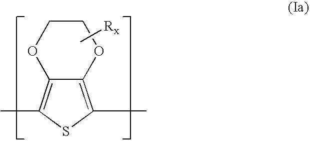
wherein,
R and x have the meaning given in claim 1.

3. The composition of claim 1 wherein polymer (B) is selected from polystyrenesulfonic acid polymers.

4. The composition of claim 1 wherein polymer (C) is copolymer of tetrafluoroethylene and of the trifluorovinylether of poly(hexafluoro propylene oxide)mono(tetrafluoro vinyl sulfonic acid)ethers.

5. The composition of claim 1 wherein said composition has a weight ratio of polythiophene (A) to polymer (C) of from 1:2 to 1:15.

6. The composition of claim 1 wherein said composition has a weight ratio of polythiophene (A) to polymer (B) of from 1:2 to 1:25.

7. The composition of claim 1 further comprising at least one polar diluent (D).

8. The composition of claim 7 wherein said polar diluent (D) is selected from the group consisting of water, alcohols and mixtures thereof.

9. The composition of claim 8 wherein said alcohols are selected from the group consisting of methanol, ethanol, n-popanol, 2-propanol, n-butanol and mixtures thereof.

10. An article of manufacture selected from the group consisting of electroluminescent arrangements, organic solar cells, organic laser diodes, organic thin film transistors, organic field effect transistors, electrodes and electrically conductive coatings, wherein said article comprises the composition of claim 1.

11. An electroluminescent arrangement comprising at least one layer selected from the group consisting of hole-injecting layers and hole-transporting layers, wherein said hole-injecting layers and hole-transporting layers each independently comprise the composition of claim 1.

12. An electroluminescent arrangement comprising:
a substrate;
at least two electrode layers;
at least one emitter layer; and
at least one hole-injecting layer,
wherein,
at least one electrode layer abuts said substrate,
said emitter layer is interposed between two electrode layers, and
at least one hole-injecting layer is interposed between one of said electrode layers and said emitter layer, and
further wherein,
said hole-injecting layer comprises the composition of claim 1.
